(19) United States
(12) Patent Application Publication
(10) Pub. No.: US 2025/0054833 A1
(43) Pub. Date: Feb. 13, 2025

(54) CONTROLLING AN IRON AND MAGNETIC SLURRY IN SEMICONDUCTOR ASSEMBLY

(71) Applicant: Lenovo (United States) Inc., Morrisville, NC (US)

(72) Inventors: Mark K. Summerville, Apex, NC (US); Sandy Collins, Durham, NC (US); Justin Michael Ringuette, Cary, NC (US); Thomas E. Annunziata, Raleigh, NC (US); Mark Christopher Heidenfeldt, Apex, NC (US)

(21) Appl. No.: 18/622,415

(22) Filed: Mar. 29, 2024

Related U.S. Application Data
(63) Continuation-in-part of application No. 18/447,793, filed on Aug. 10, 2023.

(51) Int. Cl. H01L 23/373; H01L 23/00

(52) U.S. Cl. CPC H01L 23/3736; H01L 24/29; H01L 24/32; H01L 24/83; H01L 2224/26175; H01L 2224/29105; H01L 2224/29113; H01L 2224/2916; H01L 2224/32245; H01L 2224/83007

(57) ABSTRACT

A substrate for electronic circuitry includes a ferromagnetic material and a slurry positioned in proximity to the ferromagnetic material. The slurry includes a plurality of magnets. The plurality of magnets can be spherical magnets. The slurry can include gallium and/or bismuth.

### RELATED APPLICATIONS

This application is a continuation in part of U.S. application Ser. No. 18/447,793, filed on Aug. 10, 2023, the content of which is incorporated herein by reference.

### TECHNICAL FIELD

Embodiments described herein generally relate to semiconductor assembly in computers or other electronics, and in an embodiment, but not by way of limitation, controlling an iron slurry and/or controlling a slurry containing one or more magnets in connection with semiconductor assembly.

### BACKGROUND

Galinstan is a brand name for an alloy composed of gallium, indium and tin that is used extensively in semiconductor assembly. It is composed of 68.5% Ga, 21.5% In, and 10.0% Sn (by weight), it melts at −19° C. (−2° F.) and is thus liquid at room temperature. However, it is not a eutectic alloy but a near eutectic alloy. In scientific literature, Galinstan is also used as an acronym denoting the eutectic composition of the alloy of Ga—In—Sn, which melts at around +11° C. (52° F.). The composition of both alloys is roughly the same, although Galinstan, a company's commercial technical product, likely has added flux to improve flowability, to reduce melting temperature, and to reduce surface tension. Thus, the physical properties of the Galinstan and the pure eutectic alloy EGaInSn differ slightly. Due to the low toxicity and low reactivity of its component metals, in many applications, Galinstan has replaced the toxic liquid mercury or the reactive NaK (sodium-potassium) alloy.

When using Galinstan in the assembly of semiconductors, it is difficult to apply to a printed circuit board (PCB). In some cases, the application of Galinstan causes the processor and system board to short circuit. Also, thermal cycling may result in some Galinstan escaping the interface between the heat sink and the chip, which wreaks havoc with processor pins and circuit boards. Additionally, Galinstan can be corrosive to metal, so unprotected aluminum heat sinks cannot be used with it. Also, coatings and dams are used to protect and block free Galinstan from moving around on a circuit board.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings.

FIG. 1 illustrates an embodiment of a substrate, electronic circuitry, a magnet and a ferromagnetic slurry.

FIG. 2 illustrates an embodiment of a process of applying a ferromagnetic slurry to a semiconductor chip.

FIG. 3 illustrates another process of applying a ferromagnetic slurry to a semiconductor chip.

FIG. 4 illustrates an embodiment of a substrate, electronic circuitry, a ferromagnetic material, and a slurry including a plurality of magnets.

FIGS. 5A and 5B illustrate an embodiment of a process of applying a slurry including a plurality of magnets to a semiconductor chip.

FIG. 6 illustrates another embodiment of a process of applying a slurry including a plurality of magnets to a semiconductor chip.

### DETAILED DESCRIPTION

In an embodiment, a slurry of iron powder with Galinstan in a magnetic field raises the viscosity of a slurry, thereby helping to contain the Galinstan when fabricating semiconductors. Iron has two and a half times the thermal conductivity of Galinstan, so it directly improves the thermal interface in comparison with Galinstan alone. Iron magnets are embedded in a heat sink to keep the iron-Galinstan slurry where desired and to reduce the tendency to escape the interface. In another embodiment, the magnets are placed around the heat sink and serve as a barrier. This method of containment still allows thermal expansion and contraction at the interface. In an embodiment, Neodymium magnets are used and these cause no interference with normal computer operation. In another embodiment, the magnets are placed under the processor in order to protect the plane of the processor from penetration by the Galinstan iron slurry.

In a further embodiment, one or more magnets are placed into a liquid or slurry containing Galliston and/or Bismuth, and the liquid or slurry is extruded or otherwise placed onto a substrate in a semiconductor fabrication process. The substrate includes one or more sections of strategically placed ferromagnetic material. The liquid with the magnets and the ferromagnetic material interact, thereby controlling the placement of the liquid on the substrate during the semiconductor fabrication process. The ferromagnetic material can be embedded in a heat sink to keep the Galinstan-magnet slurry where desired and to reduce the tendency to escape the interface. In another embodiment, the ferromagnetic material can be separate from the heat sink, and placed around the heat sink, thereby serving as a barrier. This method of containment still allows thermal expansion and contraction at the interface. In another embodiment, Neodymium magnets are used in the slurry and these magnets cause no interference with normal computer operation. In a further embodiment, the ferromagnetic material is placed under the processor in order to protect the plane of the processor from penetration by the Galinstan-magnet slurry.

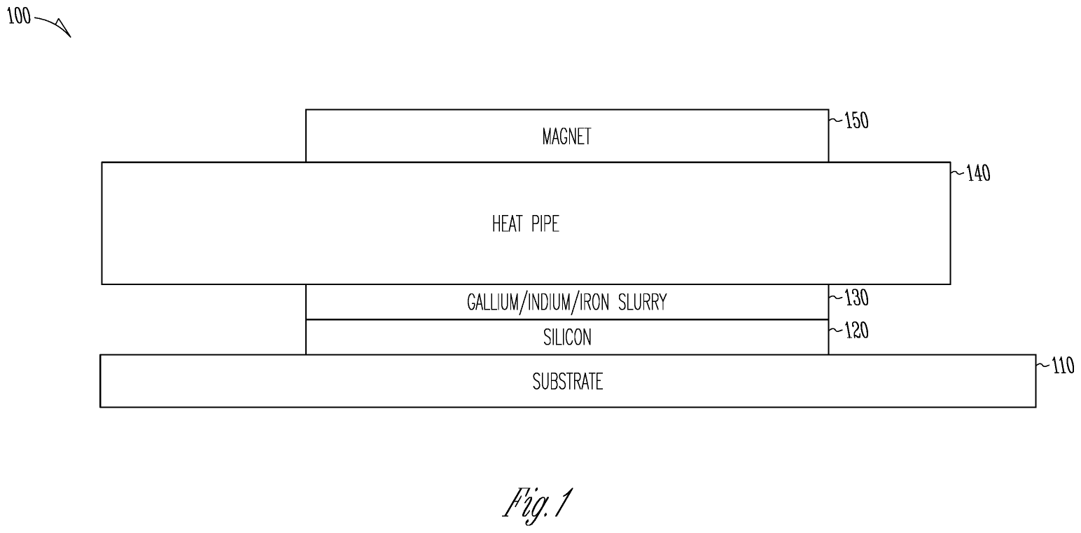

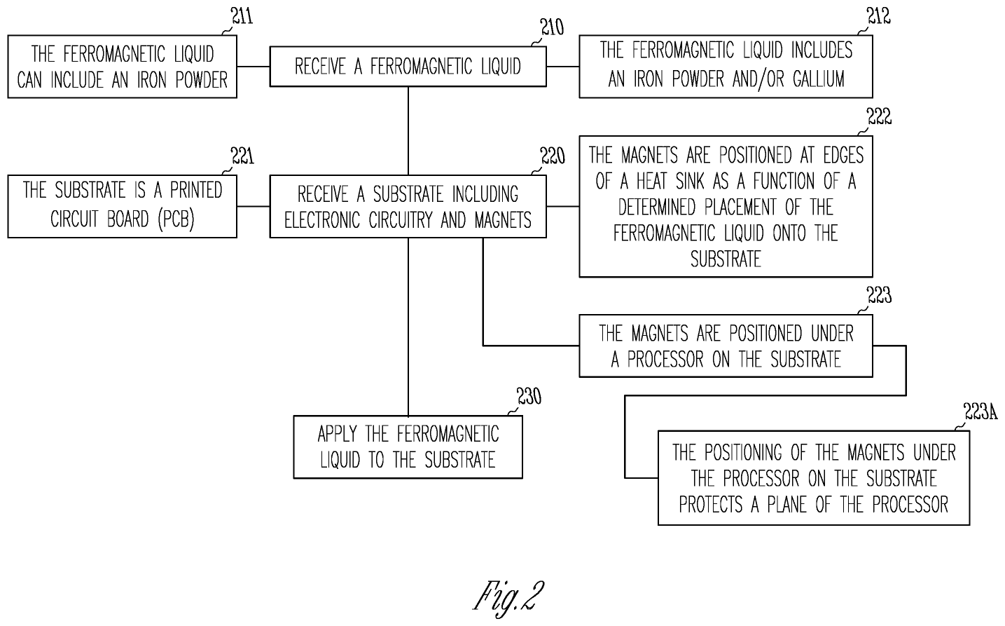

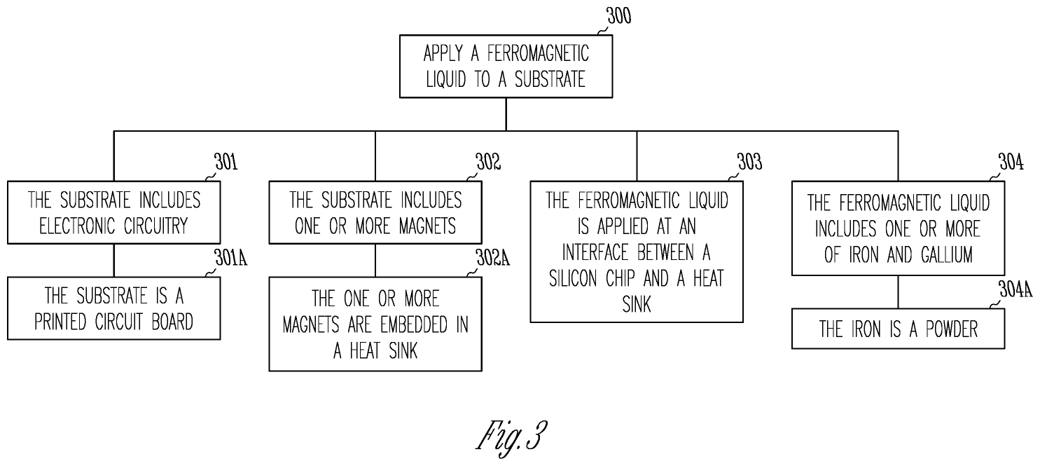

FIG. 1 illustrates an example embodiment of a system 100 for controlling an iron slurry in semiconductor assembly. Silicon 120 is deposited on a substrate 110. In an embodiment, the substrate is a printed circuit board (PCB). A ferromagnetic liquid or slurry 130 is placed on the silicon 120. In an embodiment, the ferromagnetic slurry includes one or more of iron, indium and gallium. The iron can be in the form of an iron powder. A heat sink or heat pipe 140 is positioned on the ferromagnetic slurry 130, and a magnet 150 is positioned on the heat sink 140. In another embodiment, the magnet 140 is embedded in the heat pipe or heat sink 140. In another embodiment, the magnet 140 can be positioned below the silicon 120. As noted above, and as further detailed in FIGS. 2 and 3, this arrangement allows for controlling the placement of the iron slurry on a semiconductor chip.

FIGS. 2 and 3 illustrate example embodiments of a system and process for controlling the application of a ferromagnetic slurry to a substrate. FIGS. 2 and 3 include a number of process and feature blocks 210-230 and 300-304A respectively. Though arranged substantially serially in the example of FIGS. 2 and 3, other examples may reorder the blocks, omit one or more blocks, and/or execute two or more blocks in parallel using multiple processors or a single processor organized as two or more virtual machines or sub-processors.

Referring now specifically to FIG. 2, at 210, a ferromagnetic liquid is received, acquired and/or secured, and at 220, a substrate is received, acquired and/or secured. The ferromagnetic liquid can include an iron powder (211). The iron powder raises a viscosity of the ferromagnetic liquid in the presence of a magnetic field. The ferromagnetic liquid can include one or more of an iron powder and gallium (212). The substrate includes electronic circuitry and one or more magnets. In a particular embodiment, the substrate is a printed circuit board (PCB) (221). The one or more magnets can be positioned at one or more edges of a heat sink as a function of a determined placement of the ferromagnetic liquid onto the substrate (222). The one or more magnets can be positioned under a processor on the substrate (223). The positioning of the one or more magnets under the processor on the substrate protects a plane of the processor (223A). At 230, the ferromagnetic liquid is applied to the substrate.

Referring now specifically to FIG. 3, at 300, a ferromagnetic liquid is applied to a substrate. The substrate includes electronic circuitry (301), and in a particular embodiment the substrate is a printed circuit board (301A). As indicated at 302, the substrate includes one or more magnets, and as further indicated at 302A, the one or more magnets can be embedded in a heat sink. The ferromagnetic liquid is applied at an interface between a silicon chip and a heat sink (303). In an embodiment, the ferromagnetic liquid includes one or more of iron and gallium (304). As indicated at 304A, the iron can be a powder. The iron powder increases the viscosity of the ferromagnetic liquid in the presence of a magnetic field.

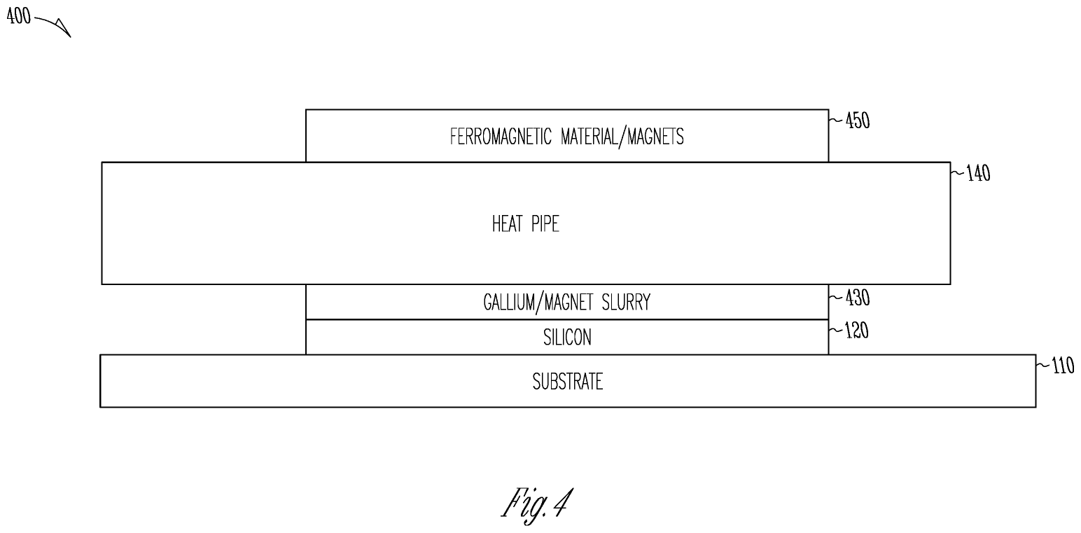

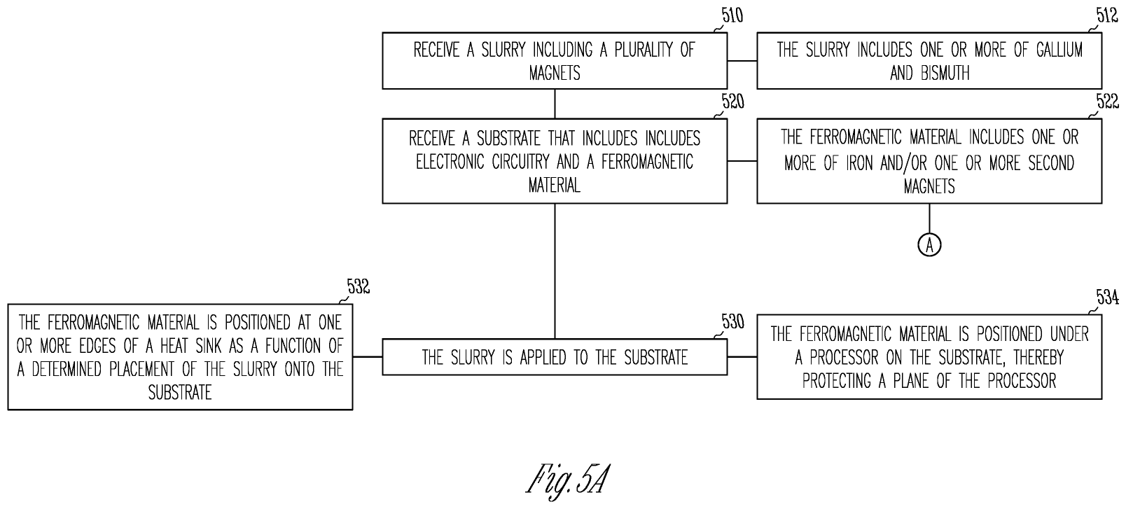

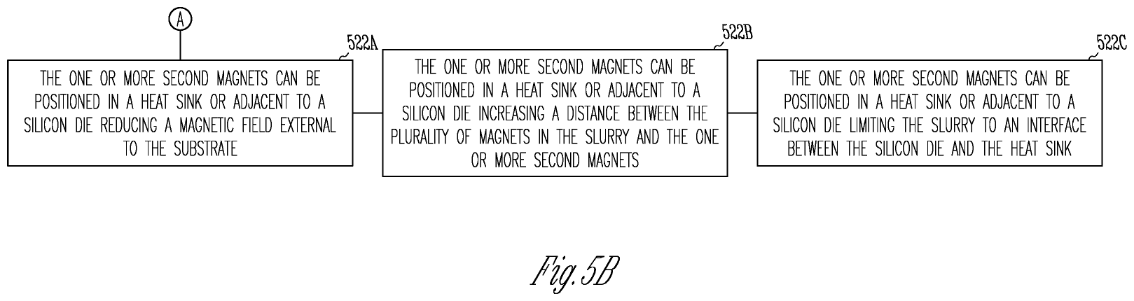

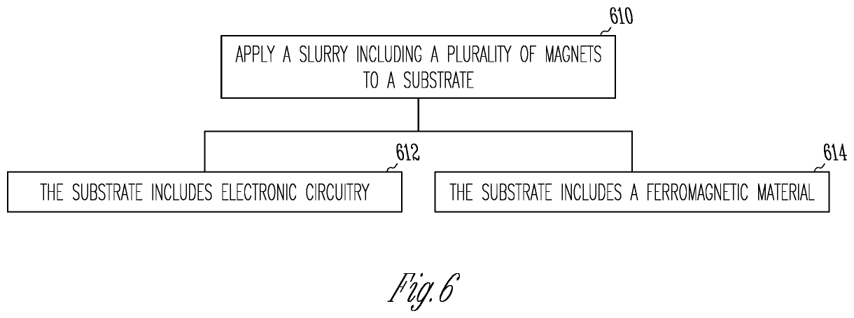

FIG. 4 illustrates an example embodiment of a system 400 for controlling a slurry that includes a plurality of magnets in semiconductor assembly. Silicon 120 is deposited on a substrate 110. In an embodiment, the substrate is a printed circuit board (PCB). A thermal interface material (TIM) such as a liquid or slurry 430 containing one or more magnets is placed on the silicon 120. The slurry 430 may also contain gallium or bismuth. A heat sink or heat pipe 140 is positioned on the magnet slurry 430, and a ferromagnetic material 450 is positioned on the heat sink 140. The ferromagnetic material 450 can include additional magnets. In another embodiment, the ferromagnetic material 450 is embedded in the heat pipe or heat sink 140. In another embodiment, the ferromagnetic material 450 can be positioned below the silicon 120. As noted above, and as further detailed in FIGS. 5 and 6, this arrangement allows for controlling the placement of the magnet slurry on a semiconductor chip.

The embodiments disclosed herein describe a magnetic field generated on one side or the other of a thermal interface. In the embodiments of FIGS. 4, 5A, 5B and 6, weaker magnets can be placed on both sides of the thermal interface to minimize the overall magnetic field and to enable an increase in the separation between the two sides of the thermal interface. Spherical and/or BB style 1 mm rare earth magnets can be used in a slurry, and additional magnets can be used in the heat sink as an iron framing. The gap can then be increased between the magnets in the heat sink and the thermal interface, and/or the strength of the magnets in the heat sink can be reduced. These techniques and structures can minimize the magnetic fields associated with the magnetized liquid metal or slurry, or these techniques and structures can be used to maximize the distance between the thermal interface and the heat sink magnetic material.

In the disclosed embodiments, any magnets could be used, depending mainly on the field strength required, shape, polarity, and maximum temperature of the application. A common Neodymium Iron Boride magnet with Nickel plating is sufficient. An arrangement could be bar magnets in or on the heat sink, and small sphere magnets in the thermal interface. Typical thermal interfaces are 100 to 200 microns. In an embodiment, 1 mm spherical NdFeB magnets are placed in the thermal interface, and 2.6 mm thick and 1 inch diameter disk NdFeB magnets are placed in the heat sink, with the spacing between the two magnets at 1 mm apart, oriented with the same north-south direction. The spheres can orient themselves. The surface field strengths of these magnets are in the range of 1400-1600 Gauss for a flat surface of the disks, and 10-50 gauss for the 1 mm spheres.

FIGS. 5A, 5B and 6 illustrate example embodiments of a system and process for controlling the application of a slurry including a plurality of magnets to a substrate. FIGS. 5A, 5B and 6 include a number of process and feature blocks 510-534 and 610-614 respectively. Though arranged substantially serially in the example of FIGS. 5A, 5B and 6, other examples may reorder the blocks, omit one or more blocks, and/or execute two or more blocks in parallel using multiple processors or a single processor organized as two or more virtual machines or sub-processors.

Referring now to FIGS. 5A and 5B, at 510, a slurry including a plurality of magnets is received, acquired and/or secured. The slurry can include one or more of gallium and bismuth (512).

At 520, a substrate received, acquired and/or secured. The substrate includes electronic circuitry and a ferromagnetic material. The ferromagnetic material can include one or more of iron and/or one or more second magnets (522). The one or more second magnets can be positioned in a heat sink or adjacent to a silicon die, which reduces a magnetic field external to the substrate (522A). The positioning of the more or more second magnets in a heat sink or adjacent to a silicon die also can increase a distance between the plurality of magnets in the slurry and the one or more second magnets (522B), and can also limit the slurry to an interface between the silicon die and the heat sink (522C).

At 530, the slurry is applied to the substrate. As noted at 532, the ferromagnetic material can be positioned at one or more edges of a heat sink as a function of a determined placement of the slurry onto the substrate. As indicated at 534, the ferromagnetic material can be positioned under a processor on the substrate, thereby protecting a plane of the processor.

Referring now to FIG. 6, at 610, a slurry including one or more magnets is applied to a substrate. As noted at 612, the substrate includes electronic circuitry, and as noted at 614, the substrate includes a ferromagnetic material.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

### EXAMPLES

Example No. 1 is a substrate for electronic circuitry comprising one or more magnets; and a ferromagnetic liquid positioned in proximity to the one or more magnets.

Example No. 2 includes all the features of Example No. 1, and optionally includes a substrate the substrate comprises a printed circuit board (PCB).

Example No. 3 includes all the features of Example Nos. 1-2, and optionally includes a substrate wherein the ferromagnetic liquid is positioned at an interface between a silicon chip and a heat sink.

Example No. 4 includes all the features of Example Nos. 1-3, and optionally includes a substrate wherein the ferromagnetic liquid comprises one or more of iron and gallium.

Example No. 5 includes all the features of Example Nos. 1-4, and optionally includes a substrate wherein the iron comprises an iron powder.

Example No. 6 includes all the features of Example Nos. 1-5, and optionally includes a substrate wherein the one or more magnets are embedded in a heat sink.

Example No. 7 includes all the features of Example Nos. 1-6, and optionally includes a substrate wherein the magnet is positioned below a silicon chip.

Example No. 8 is a process comprising receiving a ferromagnetic liquid; receiving a substrate, the substrate comprising electronic circuitry and one or more magnets; and applying the ferromagnetic liquid to the substrate.

Example No. 9 includes all the features of Example No. 8, and optionally includes a process wherein the ferromagnetic liquid comprises an iron powder, and wherein the iron powder raises a viscosity of the ferromagnetic liquid.

Example No. 10 includes all the features of Example Nos. 8-9, and optionally includes a process wherein the one or more magnets are positioned at one or more edges of a heat sink as a function of a determined placement of the ferromagnetic liquid onto the substrate.

Example No. 11 includes all the features of Example Nos. 8-10, and optionally includes a process wherein the one or more magnets are positioned under a processor on the substrate.

Example No. 12 includes all the features of Example Nos. 8-11, and optionally includes a process wherein the positioning of the one or more magnets under the processor on the substrate protects a plane of the processor.

Example No. 13 includes all the features of Example Nos. 8-12, and optionally includes a process wherein the ferromagnetic liquid comprises one or more of an iron powder and gallium.

Example No. 14 includes all the features of Example Nos. 8-13, and optionally includes a process wherein the substrate comprises a printed circuit board (PCB).

Example No. 15 is a process comprising applying a ferromagnetic liquid to a substrate; wherein the substrate comprises electronic circuitry; and wherein the substrate comprises one or more magnets.

Example No. 16 includes all the features of Example No. 15, and optionally includes a process wherein the substrate comprises a printed circuit board (PCB).

Example No. 17 includes all the features of Example Nos. 15-16, and optionally includes a process wherein the ferromagnetic liquid is applied at an interface between a silicon chip and a heat sink.

Example No. 18 includes all the features of Example Nos. 15-17, and optionally includes a process wherein the ferromagnetic liquid comprises one or more of iron and gallium.

Example No. 19 includes all the features of Example Nos. 15-18, and optionally includes a process wherein the iron comprises a powder, and the iron powder increases the viscosity of the ferromagnetic liquid in the presence of a magnetic field.

Example No. 20 includes all the features of Example Nos. 15-19, and optionally includes a process wherein the one or more magnets are embedded in a heat sink.

Example No. 1A is a substrate for electronic circuitry comprising a ferromagnetic material; and a slurry positioned in proximity to the ferromagnetic material, the slurry comprising a plurality of magnets.

Example No. 2A includes all the features of Example No. 1A, and optionally includes a substrate wherein the substrate comprises a printed circuit board (PCB).

Example No. 3A includes all the features of Example Nos. 1A-2A, and optionally includes a substrate wherein the slurry is positioned at an interface between a silicon die and a heat sink.

Example No. 4A includes all the features of Example Nos. 1A-3A, and optionally includes a substrate wherein the ferromagnetic material comprises one or more of iron and/or one or more second magnets.

Example No. 5A includes all the features of Example Nos. 1A-4A, and optionally includes a substrate wherein the one or more second magnets are positioned in a heat sink or adjacent to a silicon die, thereby reducing a magnetic field external to the substrate.

Example No. 6A includes all the features of Example Nos. 1A-5A, and optionally includes a substrate wherein the one or more second magnets are positioned in a heat sink or adjacent to a silicon die, thereby increasing a distance between the plurality of magnets and the one or more second magnets.

Example No. 7A includes all the features of Example Nos. 1A-6A, and optionally includes a substrate wherein the one or more second magnets are positioned in a heat sink or adjacent to a silicon die, thereby limiting the slurry to an interface between the silicon die and the heat sink.

Example No. 8A includes all the features of Example Nos. 1A-7A, and optionally includes a substrate wherein the ferromagnetic material is embedded in a heat sink.

Example No. 9A includes all the features of Example Nos. 1A-8A, and optionally includes a substrate wherein the ferromagnetic material is positioned below a silicon die.

Example No. 10A includes all the features of Example Nos. 1A-9A, and optionally includes a substrate wherein the slurry comprises one or more of gallium and bismuth.

Example No. 11A includes all the features of Example Nos. 1A-10A, and optionally includes a substrate wherein the plurality of magnets comprises a plurality of spherical magnets.

Example No. 12A is a process receiving a slurry comprising a plurality of magnets; receiving a substrate, the substrate comprising electronic circuitry and a ferromagnetic material; and applying the slurry to the substrate.

Example No. 13A includes all the features of Example No. 12A, and optionally includes a proces wherein the ferromagnetic material is positioned at one or more edges of a heat sink as a function of a determined placement of the slurry onto the substrate.

Example No. 14A includes all the features of Example No. 12A-13A, and optionally includes a process wherein the ferromagnetic material is positioned under a processor on the substrate, thereby protecting a plane of the processor.

Example No. 15A includes all the features of Example No. 12A-14A, and optionally includes a process wherein the ferromagnetic material comprises one or more of iron and/or one or more second magnets.

Example No. 16A includes all the features of Example No. 12A-15A, and optionally includes a process wherein the one or more second magnets are positioned in a heat sink or adjacent to a silicon die, thereby reducing a magnetic field external to the substrate.

Example No. 17A includes all the features of Example No. 12A-16A, and optionally includes a process wherein the one or more second magnets are positioned in a heat sink or adjacent to a silicon die, thereby increasing a distance between the plurality of magnets and the one or more second magnets.

Example No. 18A includes all the features of Example No. 12A-17A, and optionally includes a process wherein the one or more second magnets are positioned in a heat sink or adjacent to a silicon die, thereby limiting the slurry to an interface between the silicon die and the heat sink.

Example No. 19A includes all the features of Example No. 12A-18A, and optionally includes a process wherein the slurry comprises one or more of gallium and bismuth.

Example No. 20A is a process comprising applying a slurry comprising a plurality of magnets to a substrate; wherein the substrate comprises electronic circuitry; and wherein the substrate comprises a ferromagnetic material.

1. A substrate for electronic circuitry comprising:
a ferromagnetic material; and
a slurry positioned in proximity to the ferromagnetic material, the slurry comprising a plurality of magnets.

2. The substrate of claim 1, wherein the substrate comprises a printed circuit board (PCB).

3. The substrate of claim 1, wherein the slurry is positioned at an interface between a silicon die and a heat sink.

4. The substrate of claim 1, wherein the ferromagnetic material comprises one or more of iron and/or one or more second magnets.

5. The substrate of claim 4, wherein the one or more second magnets are positioned in a heat sink or adjacent to a silicon die, thereby reducing a magnetic field external to the substrate.

6. The substrate of claim 4, wherein the one or more second magnets are positioned in a heat sink or adjacent to a silicon die, thereby increasing a distance between the plurality of magnets and the one or more second magnets.

7. The substrate of claim 4, wherein the one or more second magnets are positioned in a heat sink or adjacent to a silicon die, thereby limiting the slurry to an interface between the silicon die and the heat sink.

8. The substrate of claim 1, wherein the ferromagnetic material is embedded in a heat sink.

9. The substrate of claim 8, wherein the ferromagnetic material is positioned below a silicon die.

10. The substrate of claim 1, wherein the slurry comprises one or more of gallium and bismuth.

11. The substrate of claim 1, wherein the plurality of magnets comprises a plurality of spherical magnets.

12. A process comprising:
receiving a slurry comprising a plurality of magnets;
receiving a substrate, the substrate comprising electronic circuitry and a ferromagnetic material; and
applying the slurry to the substrate.

13. The process of claim 12, wherein the ferromagnetic material is positioned at one or more edges of a heat sink as a function of a determined placement of the slurry onto the substrate.

14. The process of claim 12, wherein the ferromagnetic material is positioned under a processor on the substrate, thereby protecting a plane of the processor.

15. The process of claim 12, wherein the ferromagnetic material comprises one or more of iron and/or one or more second magnets.

16. The process of claim 15, wherein the one or more second magnets are positioned in a heat sink or adjacent to a silicon die, thereby reducing a magnetic field external to the substrate.

17. The process of claim 15, wherein the one or more second magnets are positioned in a heat sink or adjacent to a silicon die, thereby increasing a distance between the plurality of magnets and the one or more second magnets.

18. The process of claim 15, wherein the one or more second magnets are positioned in a heat sink or adjacent to a silicon die, thereby limiting the slurry to an interface between the silicon die and the heat sink.

19. The process of claim 12, wherein the slurry comprises one or more of gallium and bismuth.

20. A process comprising:
applying a slurry comprising a plurality of magnets to a substrate;
wherein the substrate comprises electronic circuitry; and
wherein the substrate comprises a ferromagnetic material.
